(19) United States
(12) Patent Application Publication
(10) Pub. No.: US 2025/0098443 A1
(43) Pub. Date: Mar. 20, 2025

(54) DISPLAY APPARATUS

(71) Applicant: Samsung Display Co., Ltd., Yongin-si (KR)

(72) Inventor: Heechul Lee, Yongin-si (KR)

(21) Appl. No.: 18/818,321

(22) Filed: Aug. 28, 2024

(30) Foreign Application Priority Data
Sep. 15, 2023 (KR) 10-2023-0123322

(51) Int. Cl. H10K 59/127; H10K 59/123; H10K 59/131; H10K 102/10

(52) U.S. Cl. CPC H10K 59/127; H10K 59/123; H10K 59/131; H10K 2102/10

(57) ABSTRACT

A display apparatus includes a substrate, a semiconductor layer over the substrate, and including a first area, a second area, and a channel area, a gate electrode over the semiconductor layer, and overlapping the channel area, and a pixel electrode electrically connected to the first area that is in one direction from the channel area of the semiconductor layer, wherein the second area is farther than the first area from the channel area.

### CROSS-REFERENCE TO RELATED APPLICATION

The present application claims priority to, and the benefit of, Korean Patent Application No. 10-2023-0123322, filed on Sep. 15, 2023, in the Korean Intellectual Property Office, the entire disclosure of which is incorporated herein by reference.

### BACKGROUND

### 1. Field

One or more embodiments relate to a display apparatus that may be used for a long period of time even when using an existing battery.

### 2. Description of the Related Art

In general, display apparatuses include display panels and operate by receiving power, etc. from a power supply. A portable display apparatus may include a battery, etc. as a power supply. However, because of the limited amount of power discharged from the battery, the battery needs to be replaced or recharged to keep using the portable display apparatus.

### SUMMARY

One or more embodiments are to overcome various problems including the aforementioned one and include a display apparatus that may be used for an extended period of time even when using an existing battery. However, this is merely an example, and the scope of the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a substrate, a semiconductor layer over the substrate, and including a first area, a second area, and a channel area, a gate electrode over the semiconductor layer, and overlapping the channel area, and a pixel electrode electrically connected to the first area that is in one direction from the channel area of the semiconductor layer, wherein the second area is farther than the first area from the channel area.

The second area may be in the one direction from the channel area.

The display apparatus may further include a first electrode contacting the first area, and electrically connected to the pixel electrode, and a second electrode contacting the second area.

The substrate may include a first substrate, a second substrate over the first substrate, and a substrate intermediate layer between the first substrate and the second substrate.

The substrate intermediate layer may include amorphous silicon or crystalline silicon.

The channel area may be doped with a dopant having a first type that is one of an n type and a p type, and each of the first area and the second area may be doped with a dopant having a second type that is another of the n type and p type.

A doping concentration in the second area may be higher than a doping concentration in the first area.

A third area that is in another direction from the channel area may be doped with the dopant having the second type.

A doping concentration in the second area may be higher than a doping concentration in the third area.

A doping concentration in the first area may be substantially equal to a doping concentration in the third area.

The display apparatus may further include a battery configured to drive the display apparatus, wherein the second area is electrically connected to the battery.

The second area may be electrically connected to a rectifier circuit that is electrically connected to the battery.

The gate electrode may be of a driving transistor.

According to one or more embodiments, a display apparatus includes a substrate, a gate electrode over the substrate, a semiconductor layer between the substrate and the gate electrode, and including a first area, a second area, and a channel area overlapping the gate electrode, the first area being in one direction from the channel area, the second area being farther from the channel area than the first area, a charging connection electrode contacting the second area, and a battery electrically connected to the charging connection electrode.

The second area may be in the one direction from the channel area.

The display apparatus may further include a transmission line contacting the first area, and a pixel electrode electrically connected to the transmission line.

The substrate may include a first substrate, a second substrate over the first substrate, and a substrate intermediate layer between the first substrate and the second substrate.

The substrate intermediate layer may include amorphous silicon or crystalline silicon.

The channel area may be doped with a dopant having a first type that is one of an n type and a p type, and the first area and the second area may be doped with a dopant having a second type that is another of the n type and p type.

A doping concentration in the second area may be higher than a doping concentration in the first area.

Other aspects other than those described above will become apparent from the following detailed description, claims and drawings for carrying out the disclosure.

### BRIEF DESCRIPTION OF THE DRAWINGS

The above and other aspects of certain embodiments of the disclosure will be more apparent from the following description taken in conjunction with the accompanying drawings, in which:

FIG. 1 is a schematic plan view of a display panel of a display apparatus, according to one or more embodiments;

FIG. 2 is an equivalent circuit diagram of a pixel included in the display panel of FIG. 1;

FIG. 3 is a schematic layout showing locations of transistors, capacitors, and the like in pixels of the display panel of FIG. 1;

FIGS. 4 to 10 are schematic layouts showing, for each level, components, such as transistors and capacitors, which are included in the display panel of FIG. 3;

FIG. 11 is a schematic cross-sectional view of the display panel of FIG. 3, taken along the line I-I′ of FIG. 3; and

FIG. 12 is a schematic conceptual view of a display apparatus according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions, such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions, such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

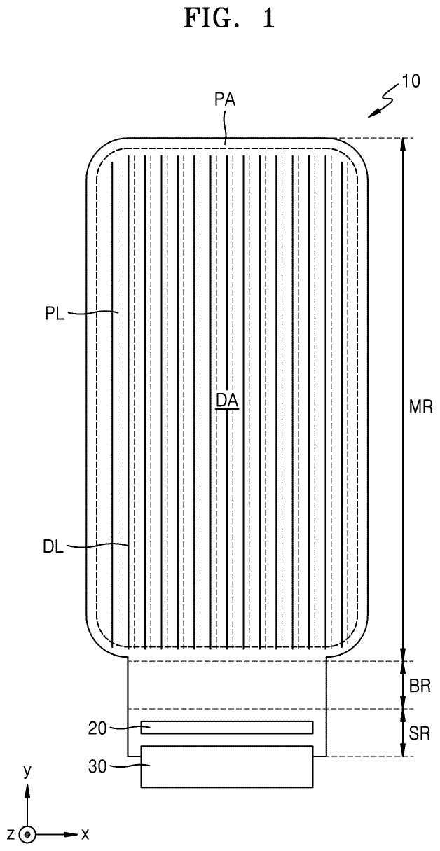

FIG. 1 is a schematic plan view of a display panel 10 of a display apparatus, according to one or more embodiments. The display apparatus according to the present embodiment includes the display panel 10. The display apparatus including the display panel 10 may be any type of display apparatus. For example, the display apparatus may be various products, such as a smartphone, a tablet computer, a laptop, and a portable television.

The display panel 10 includes a display area DA, and a peripheral area PA outside the display area DA (e.g., in plan view). The display area DA is an area where images are displayed, and a plurality of pixels may be arranged in the display area DA. When viewed in a direction substantially perpendicular to the display panel 10, the display area DA may have various shapes, such as a circle, an oval, a polygon, and other shapes. FIG. 1 shows that the shape of the display area DA is substantially a rectangle with rounded edges.

The peripheral area PA may be arranged outside the display area DA. A width of a portion of the peripheral area PA (in an x-axis direction) may be less than a width of the display area DA (in the x-axis direction). Based on the above structure, at least a portion of the peripheral area PA may be bent if suitable.

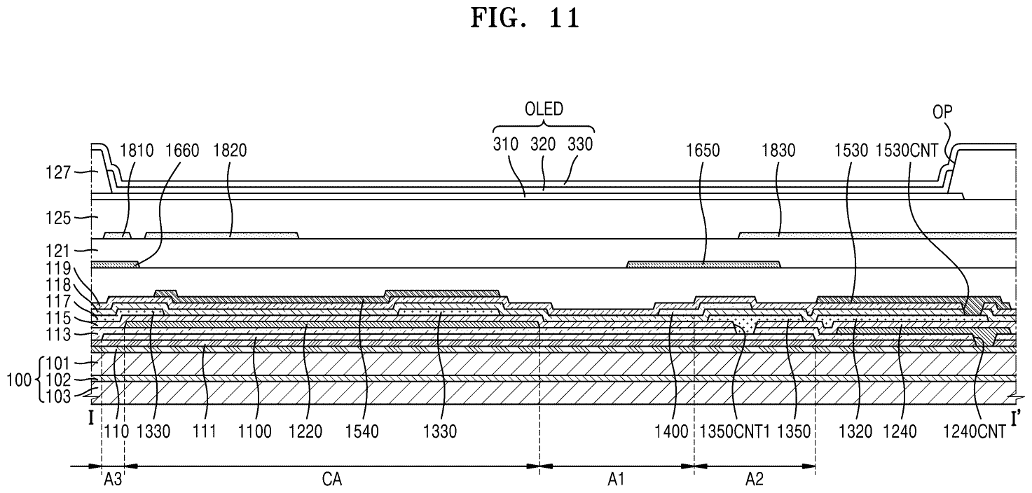

Because the display panel 10 includes a substrate 100 (e.g., see FIG. 11), it may be described that the substrate 100 includes the display area DA and the peripheral area PA described above. Hereinafter, for convenience, it is described that the substrate 100 includes the display area DA and the peripheral area PA.

In the display area DA, a plurality of data lines DL may be arranged to cross the display area DA. Likewise, in the display area DA, a plurality of power lines PL may be arranged to cross the display area DA. FIG. 1 shows for convenience that the data lines DL are indicated by solid lines and the power lines PL are indicated by dashed lines, but the data lines DL and the power lines PL may be concurrently or substantially simultaneously formed of the same material at the same level/layer.

If suitable, the display panel 10 may also include a main region MR, a bending region BR outside the main region MR, and a subregion SR arranged opposite to the main region MR with respect to the bending region BR. The display panel 10 may be bent in the bending region BR, and when viewed in the z-axis direction, at least a portion of the subregion SR may overlap the main region MR. However, the disclosure is not limited to a display apparatus that is bent, and may also be applied to a display apparatus that is not bent. The subregion SR may be a non-display area. As the display panel 10 is bent in the bending region BR, when the display apparatus is viewed from the front surface of the display apparatus (in a-z direction), the non-display area may not be visible, or a viewed area of the non-display area may decrease even though the non-display area is viewed.

A driving chip 20, etc. may be arranged in the subregion SR of the display panel 10. The driving chip 20 may include an integrated circuit for driving the display panel 10. Such an integrated circuit may be a data driving integrated circuit for generating a data signal, but one or more embodiments are not limited thereto.

The driving chip 20 may be mounted in the subregion SR of the display panel 10. The driving chip 20 may be mounted on the same surface as the display surface of the display area DA, but as described above, as the display panel 10 is bent in the bending region BR, the driving chip 20 may be located on the rear surface of the main region MR.

A printed circuit board 30, etc. may be attached to an end portion of the subregion SR of the display panel 10. The printed circuit board 30, etc. may be electrically connected to the driving chip 20, etc. through a plurality of pads arranged along an edge of the substrate.

Hereinafter, an organic light-emitting display apparatus is described as an example of the display apparatus, but the display apparatus is not limited thereto. As another example, the display apparatus may be a display apparatus, such as an inorganic light-emitting display apparatus, an inorganic EL display apparatus, or a quantum dot light-emitting display apparatus. For example, an emission layer of a display element of the display apparatus may include an organic material or an inorganic material. In addition, the display apparatus may include an emission layer and a quantum dot layer located in a path of light emitted from the emission layer.

As described above, the display panel 10 may include the substrate 100. Various components included in the display panel 10 may be located over the substrate 100. The substrate 100 may include a glass material, metals, or polymer resin. As described above, when the display panel 10 is bent in the bending region BR, the substrate 100 needs to be flexible or bendable. In this case, the substrate 100 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate.

In the display area DA, pixels are arranged. Each pixel may refer to a sub-pixel and include a display element, such as an organic light-emitting diode OLED. The pixel may emit, for example, red light, green light, blue light, or white light.

The pixels may be electrically connected to outer circuits arranged in the peripheral area PA. In the peripheral area PA, a scan-driving circuit, an emission-control-driving circuit, a pad, a power supply line, a common voltage line, and the like may be arranged. The scan-driving circuit may provide a scan signal to a pixel through a scan line. The emission-control-driving circuit may provide an emission control signal to a pixel through an emission control line. The pad arranged in the peripheral area PA of the substrate 100 may not be covered by an insulating layer, and may be exposed, and thus, the pad may be electrically connected to the printed circuit board 30. A terminal of the printed circuit board 30 may be electrically connected to the pad of the display panel 10.

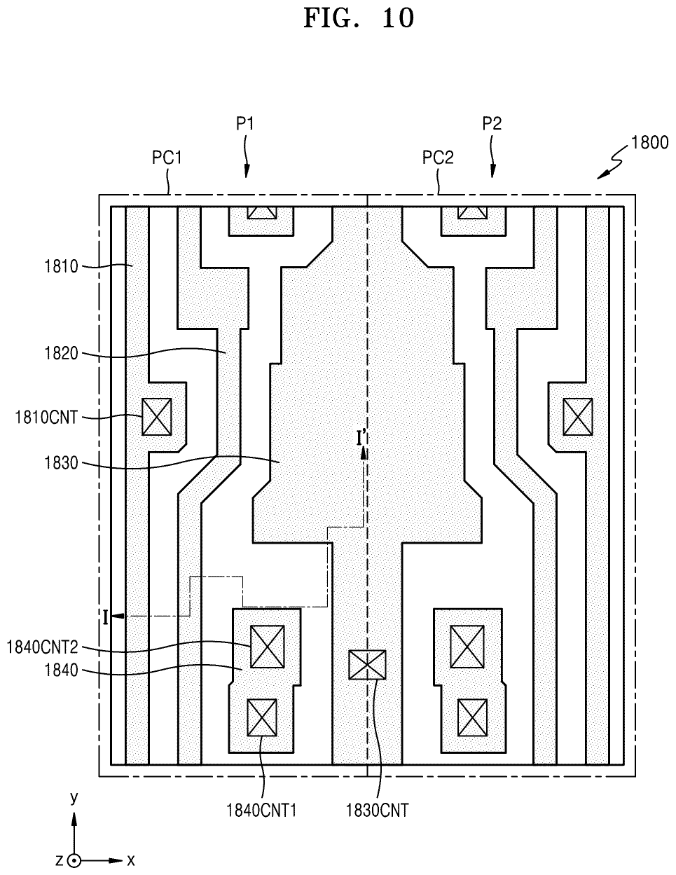

The printed circuit board 30 transmits a signal or power from a controller to the display panel 10. Control signals generated by the controller may be transmitted to driving circuits, respectively, through the printed circuit board 30. Also, the controller may transmit a first power voltage to the power supply line, and a second power voltage to the common voltage line. The first power voltage (e.g., ELVDD, or a driving voltage) may be transmitted to each pixel through a power line PL (e.g., see voltage line 1830 of FIG. 10) connected to the power supply line, and the second power voltage (e.g., ELVSS, or a common voltage) may be transmitted to a common opposite electrode 330 (e.g., see FIG. 11) of a pixel connected to the common voltage line. The common voltage line may have a loop shape with one open side in a region where the driving chip 20, etc. is located, and may partially surround the display area DA.

The controller may generate a data signal, and the generated data signal may be transmitted to the pixel through the driving chip 20 and the data line DL (e.g., see data line 1810 of FIG. 10).

For reference, the term “line” may indicate a “wire,” which is also applied to the embodiments below and modified examples.

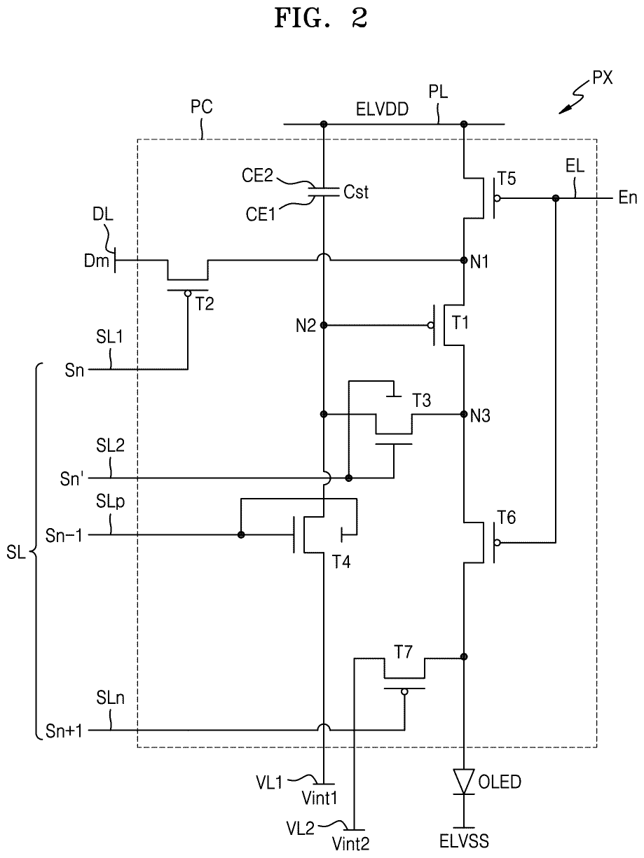

FIG. 2 is an equivalent circuit diagram of a pixel included in the display panel 10 of FIG. 1. As shown in FIG. 2, the pixel PX may include a pixel circuit PC, and an organic light-emitting diode OLED electrically connected to the pixel circuit PC.

As shown in FIG. 2, the pixel circuit PC may include a plurality of thin-film transistors T1 to T7 and a storage capacitor Cst. The thin-film transistors T1 to T7 and the storage capacitor Cst may be connected to signal lines SL1, SL2, SLp, SLn, EL, and DL, a first initialization voltage line VL1, a second initialization voltage line VL2, and a driving voltage line PL. At least any one of the above lines (e.g., the driving voltage line PL) may be shared by neighboring pixels PX.

The thin-film transistors T1 to T7 may include a driving transistor T1, a switching transistor T2, a compensation transistor T3, a first initialization transistor T4, an operation control transistor T5, an emission control transistor T6, and a second initialization transistor T7.

The organic light-emitting diode OLED may include a pixel electrode and an opposite electrode, the pixel electrode of the organic light-emitting diode OLED may be connected to the driving transistor T1 through the emission control transistor T6, and may receive a driving current, and the opposite electrode may receive the second power voltage ELVSS. The organic light-emitting diode OLED may generate light having a brightness corresponding to the driving current.

Some of the thin-film transistors T1 to T7 may each be an n-channel MOSFET (NMOS), and the others thereof may each be a p-channel MOSFET (PMOS). For example, the compensation transistor T3 and the first initialization transistor T4 among the thin-film transistors T1 to T7 may each be an NMOS, and the others thereof may each be a PMOS. Alternatively, the compensation transistor T3, the first initialization transistor T4, and the second initialization transistor T7 among the thin-film transistors T1 to T7 may each be an NMOS, and the others thereof may each be a PMOS. Alternatively, all of the thin-film transistors T1 to T7 may be NMOSs or PMOSs. The thin-film transistors T1 to T7 may include amorphous silicon or polysilicon. According to suitability, a thin-film transistor that is an NMOS may include an oxide semiconductor. Hereinafter, the compensation transistor T3 and the first initialization transistor T4 each are an NMOS including an oxide semiconductor, and the others each are a PMOS.

The signal lines may include a first scan line SL1 configured to transmit a first scan signal Sn, a second scan line SL2 configured to transmit a second scan signal Sn′, a previous scan line SLp configured to transmit a previous scan signal Sn−1 to the first initialization transistor T4, a next scan line SLn configured to transmit a next scan signal Sn+1 to the second initialization transistor T7, an emission control line EL configured to transmit an emission control signal En to the operation control transistor T5 and to the emission control transistor T6, and the data line DL crossing the first scan line SL1 and configured to transmit a data signal Dm.

The driving voltage line PL may be configured to transmit the driving voltage ELVDD to the driving transistor T1, the first initialization voltage line VL1 may be configured to transmit a first initialization voltage Vint1 for initializing the driving transistor T1, and the second initialization voltage line VL2 may be configured to transmit a second initialization voltage Vint2 for initializing the pixel electrode of the organic light-emitting diode OLED.

A driving gate electrode of the driving transistor T1 may be connected to the storage capacitor Cst through a second node N2, any one of a source area and a drain area of the driving transistor T1 may be connected to the driving voltage line PL through a first node N1 via the operation control transistor T5, and the other of the source area and the drain area of the driving transistor T1 may be electrically connected to the pixel electrode of the organic light-emitting diode OLED through a third node N3 via the emission control transistor T6. The driving transistor T1 may receive the data signal Dm according to a switching operation of the switching transistor T2, and may be configured to supply a driving current to the organic light-emitting diode OLED. That is, the driving transistor T1 may control the amount of currents flowing to the organic light-emitting diode OLED from the first node N1 electrically connected to the driving voltage line PL, according to a voltage differing according to the data signal Dm, and applied to the second node N2.

A switching gate electrode of the switching transistor T2 may be connected to the first scan line SL1 configured to transmit the first scan signal Sn, any one of a source area and a drain area of the switching transistor T2 may be connected to the data line DL, and the other thereof may be connected to the driving transistor T1 through the first node N1 while also being connected to the driving voltage line PL through the operation control transistor T5. The switching transistor T2 may be configured to transmit, to the first node N1, the data signal Dm transmitted through the data line DL according to a voltage applied to the first scan line SL1. That is, the switching transistor T2 may be turned on in response to the first scan signal Sn transmitted through the first scan line SL1, and may perform a switching operation of transmitting the data signal Dm, which is transmitted through the data line DL, to the driving transistor T1 through the first node N1.

A compensation gate electrode of the compensation transistor T3 is connected to the second scan line SL2. Any one of a source area and a drain area of the compensation transistor T3 may be connected to the pixel electrode of the organic light-emitting diode OLED through the third node N3 via the emission control transistor T6. The other of the source area and the drain area of the compensation transistor T3 may be connected to a first capacitor electrode CE1 of the storage capacitor Cst and the driving gate electrode of the driving transistor T1 through the second node N2. The compensation transistor T3 may be turned on in response to the second scan signal Sn′ transmitted through the second scan line SL2, and may diode-connect the driving transistor T1.

A first initialization gate electrode of the first initialization transistor T4 may be connected to the previous scan line SLp. Any one of a source area and a drain area of the first initialization transistor T4 may be connected to the first initialization voltage line VL1. The other of the source area and the drain area of the first initialization transistor T4 may be connected to the first capacitor electrode CE1 of the storage capacitor Cst, to the driving gate electrode of the driving transistor T1, and the like through the second node N2. The first initialization transistor T4 may apply the first initialization voltage Vint1, which is transmitted through the first initialization voltage line VL1, to the second node N2 according to a voltage applied to the previous scan line SLp. That is, the first initialization transistor T4 may be turned on in response to the previous scan signal Sn−1 transmitted through the previous scan line SLp, and may be configured to transmit the first initialization voltage Vint to the driving gate electrode of the driving transistor T1, thereby performing an initialization operation of initializing a voltage of the driving gate electrode of the driving transistor T1.

An operation control gate electrode of the operation control transistor T5 may be connected to the emission control line EL, any one of a source area and a drain area of the operation control transistor T5 may be connected to the driving voltage line PL, and the other thereof may be connected to the driving transistor T1 and the switching transistor T2 through the first node N1.

An emission control gate electrode of the emission control transistor T6 may be connected to the emission control line EL, any one of a source area and a drain area of the emission control transistor T6 may be connected to the driving transistor T1 and the compensation transistor T3 through the third node N3, and the other thereof may be electrically connected to the pixel electrode of the organic light-emitting diode OLED.

The operation control transistor T5 and the emission control transistor T6 may be concurrently or substantially simultaneously turned on in response to the emission control signal En transmitted through the emission control line EL, and may be configured to transmit the driving voltage ELVDD to the organic light-emitting diode OLED so that the driving current flows in the organic light-emitting diode OLED.

A second initialization gate electrode of the second initialization transistor T7 may be connected to the next scan line SLn, any one of a source area and a drain area of the second initialization transistor T7 may be connected to the pixel electrode of the organic light-emitting diode OLED, and the other thereof may be connected to the second initialization voltage line VL2 to receive the second initialization voltage Vint2. The second initialization transistor T7 is turned on in response to a next scan signal Sn+1 transmitted through the next scan line SLn, and initializes the pixel electrode of the organic light-emitting diode OLED. The next scan line SLn may be the same as the first scan line SL1. In this case, a corresponding scan line may be configured to transmit the same electrical signal with a time gap, and may function as either the first scan line SL1 or the next scan line SLn. That is, the next scan line SLn may be a first scan line of a pixel electrically connected to the data line DL as a pixel that is adjacent to the pixel PX of FIG. 2.

The second initialization transistor T7 may be connected to the first scan line SL1, as shown in FIG. 2. However, one or more embodiments are not limited thereto, and the second initialization transistor T7 may be connected to the emission control line EL, and may be driven according to the emission control signal En.

The storage capacitor Cst may include the first capacitor electrode CE1 and the second capacitor electrode CE2. The first capacitor electrode CE1 of the storage capacitor Cst is connected to the driving gate electrode of the driving transistor T1 through the second node N2, and the second capacitor electrode CE2 of the storage capacitor Cst is connected to the driving voltage line PL. The storage capacitor Cst may store therein electric charges corresponding to the difference between a voltage of the driving gate electrode of the driving transistor T1 and the driving voltage ELVDD.

A detailed operation of each pixel PX according to one or more embodiments is described as follows.

During an initialization period, when the previous scan signal Sn−1 is provided through the previous scan line SLp, the first initialization transistor T4 is turned on in response to the previous scan signal Sn−1, and the driving transistor T1 is initialized according to the first initialization voltage Vint1 provided through the first initialization voltage line VL1.

During a data programming period, when the first scan signal Sn and the second scan signal Sn′ are provided respectively through the first scan line SL1 and the second scan line SL2, the switching transistor T2 and the compensation transistor T3 are respectively turned on in response to the first scan signal Sn and the second scan signal Sn′. In this case, the driving transistor T1 is diode-connected by the compensation transistor T3 that is on, and biased in a forward direction. Then, a compensation voltage (Dm+Vth, where Vth has a negative value), which is generated by subtracting a threshold voltage Vth of the driving transistor T1 from the data signal Dm provided through the data line DL, is applied to the driving gate electrode of the driving transistor T1. The driving voltage ELVDD and the compensation voltage Dm+Vth are applied to both ends of the storage capacitor Cst, and electric charges corresponding to the voltage difference in the ends of the storage capacitor Cst are stored in the storage capacitor Cst.

During an emission period, the operation control transistor T5 and the emission control transistor T6 are turned on in response to the emission control signal En provided through the emission control line EL. A driving current according to the difference between the voltage of the driving gate electrode of the driving transistor T1 and the driving voltage ELVDD is generated, and the driving current is provided to the organic light-emitting diode OLED through the emission control transistor T6.

As described above, some of the thin-film transistors T1 to T7 may include oxide semiconductors. For example, the compensation transistor T3 and the first initialization transistor T4 may include oxide semiconductors.

Because polysilicon is highly reliable, an accurately intended current may be allowed to flow. Therefore, the driving transistor T1 directly affecting the brightness of the display apparatus is designed to include a semiconductor layer including polysilicon with high reliability, and thus, a high-resolution display apparatus may be realized. Because an oxide semiconductor has high carrier mobility and a low leakage current, a voltage drop is not great despite a long operation time. That is, in the case of the oxide semiconductor, because a color change in images according to the voltage drop is not noticeable even during a low-frequency operation, the display apparatus may operate at a low frequency. Therefore, the compensation transistor T3 and the first initialization transistor T4 each are designed to include an oxide semiconductor, and thus, a display apparatus in which the occurrence of a leakage current is reduced or prevented and the power consumption is reduced may be realized.

Such an oxide semiconductor is sensitive to light, and thus, some changes may be made to the amount of current, etc. because of external light. Therefore, a metal layer is arranged under the oxide semiconductor to absorb or reflect the external light. As shown in FIG. 2, in each of the compensation transistor T3 and the first initialization transistor T4 including the oxide semiconductors, gate electrodes may be respectively located over and under an oxide semiconductor layer. That is, when viewed in a direction perpendicular to an upper surface of the substrate 100 (in a z-axis direction), the metal layer arranged under the oxide semiconductor may overlap the oxide semiconductor.

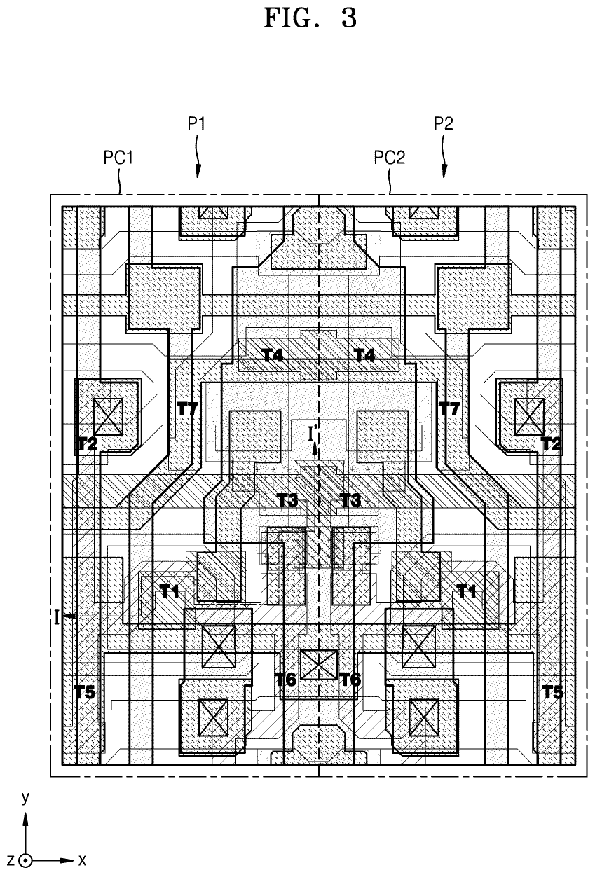

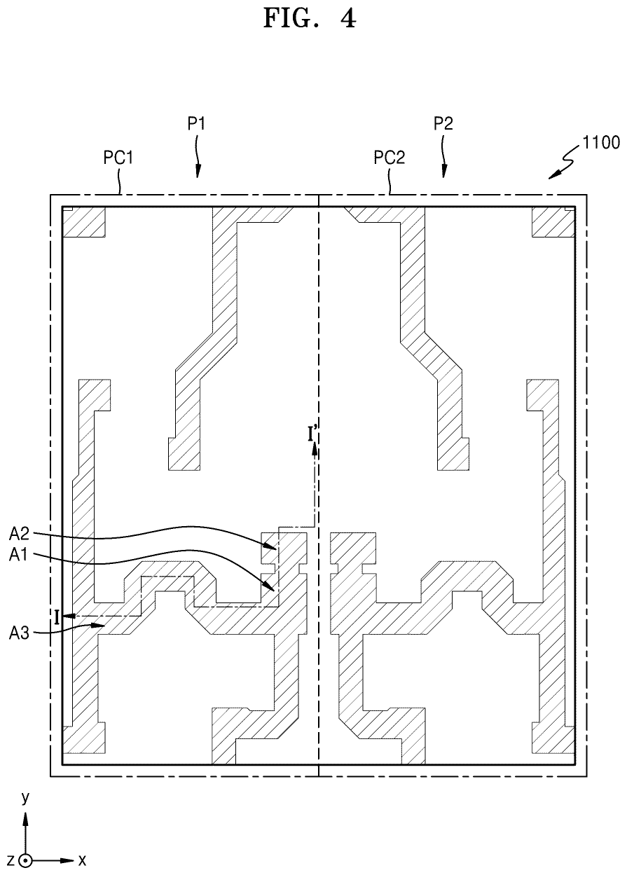

FIG. 3 is a schematic layout showing the locations of transistors, capacitors, and other components in pixels of the display panel 10 of FIG. 1, FIGS. 4 to 10 are schematic layouts showing, for respective levels, components, such as transistors and capacitors, which are included in the display panel of FIG. 3, and FIG. 11 is a schematic cross-sectional view of the display panel of FIG. 3 taken along the line I-I′ of FIG. 3.

As shown in the above drawings, the display apparatus may include a first pixel P1 and a second pixel P2 that are adjacent to each other. As shown in FIG. 3, etc., the first pixel P1 and the second pixel P2 may be symmetrical to each other with respect to a virtual line. Alternatively, the first pixel P1 may have the same configuration as the second pixel P2, instead of the symmetrical configuration. The first pixel P1 may include a first pixel circuit PC1, and the second pixel P2 may include a second pixel circuit PC2. Hereinafter, for convenience, some conductive patterns are described based on the first pixel circuit PC1, but such conductive patterns may be symmetrically arranged in the second pixel circuit PC2. The organic light-emitting diode OLED may be electrically connected to each of the first pixel circuit PC1 and the second pixel circuit PC2.

Above the substrate 100, a buffer layer 111 (e.g., see FIG. 11) including silicon oxide (SiO₂), silicon nitride (SiNₓ), or silicon oxynitride (SiOₓN_{y}) may be located. The buffer layer 111 may reduce or prevent metal atoms, impurities, or the like diffusing from the substrate 100 towards a first semiconductor layer 1100 located over the buffer layer 111. Also, the buffer layer 111 may adjust a heat supply speed during a crystallization process of forming the first semiconductor layer 1100, and thus, the first semiconductor layer 1100 may be evenly crystallized.

The first semiconductor layer 1100 shown in FIG. 4 may be located over the buffer layer 111. The first semiconductor layer 1100 may include a silicon semiconductor. For example, the first semiconductor layer 1100 may include amorphous silicon or polysilicon. In detail, the first semiconductor layer 1100 may include polysilicon crystallized at a low temperature. According to suitability, ions may be injected into at least a portion of the first semiconductor layer 1100.

As described above, the driving transistor T1, the switching transistor T2, the operation control transistor T5, the emission control transistor T6, and the second initialization transistor T7 may each be a PMOS, and in this case, the thin-film transistors are located along the first semiconductor layer 1100 shown in FIG. 4.

As shown in FIG. 4, the first semiconductor layer 1100 may include a first area A1, a second area A2, and a third area A3, which is described below.

A first gate-insulating layer 113 (e.g., see FIG. 11) may cover the first semiconductor layer 1100, and may be located over the substrate 100. The first gate-insulating layer 113 may include an insulating material. For example, the first gate-insulating layer 113 may include SiO₂, SiNₓ, SiOₓN_{y}, aluminum oxide (Al₂O₃), or the like.

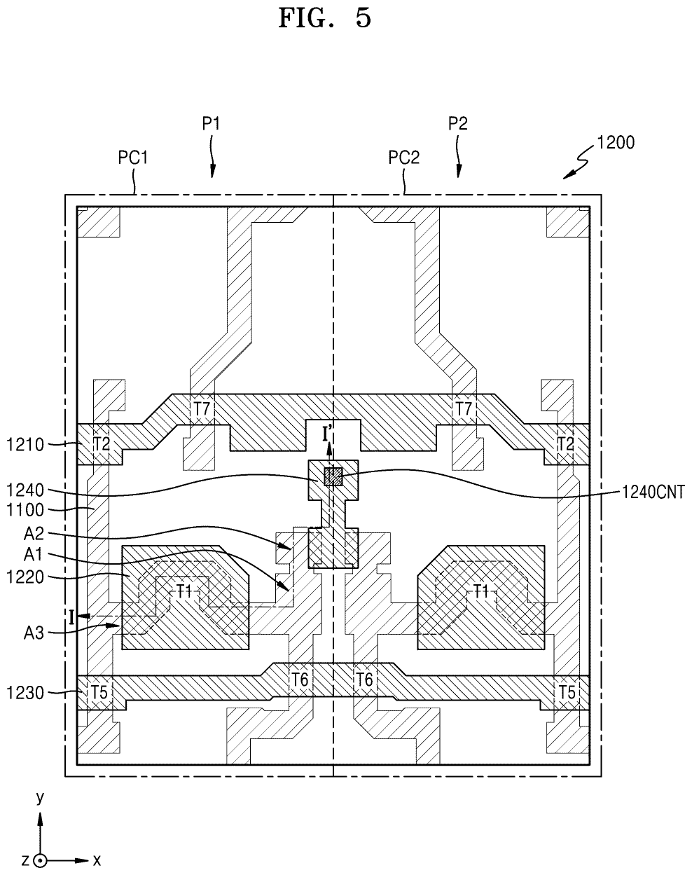

A first gate layer 1200 shown in FIG. 5 may be located over the first gate-insulating layer 113. For convenience, FIG. 5 shows the first gate layer 1200 together with the first semiconductor layer 1100. The first gate layer 1200 may include a first gate line 1210, a driving gate electrode 1220, a second gate line 1230, and a charging electrode 1240.

The first gate line 1210 may extend in a second direction (an x-axis direction). The first gate line 1210 may be the first scan line SL1 or the next scan line SLn of FIG. 2. That is, as shown in FIG. 5, for the first pixel P1, the first gate line 1210 may correspond to the first scan line SL1 of FIG. 2, and for a pixel that is adjacent to the first pixel P1 (in the +y direction), the first gate line 1210 may correspond to the next scan line SLn of FIG. 2. Accordingly, the first scan signal Sn and the next scan signal Sn+1 may be applied to pixels through the first gate line 1210. Portions of the first gate line 1210, which overlap the first semiconductor layer 1100, may be the switching gate electrode of the switching transistor T2 and the second initialization gate electrode of the second initialization transistor T7.

A driving gate electrode 1220 may have an isolated shape. The driving gate electrode 1220 may be a gate electrode of the driving transistor T1. For reference, a portion of the first semiconductor layer 1100, which overlaps the driving gate electrode 1220, and a portion around the above portion may be referred to as a driving semiconductor layer.

A portion of the first semiconductor layer 1100 that corresponds to the driving gate electrode 1220, that is, a portion of the first semiconductor layer 1100 that overlaps the driving gate electrode 1220 when viewed in a direction perpendicular to the substrate 100 (the z-axis direction), may be referred to as a channel area (CA, see FIG. 11). As shown in FIG. 11, the first area A1 and the second area A2 of the first semiconductor layer 1100 may be portions of the first semiconductor layer 1100 in one direction from the channel area CA, and the third area A3 of the first semiconductor layer 1100 may be a portion of the first semiconductor layer 1100 in the other direction from the channel area CA. The second area A2 may be located farther from the channel area CA than the first area A1.

Here, the description that the second area A2 is located farther from the channel area CA than the first area A1 is not construed as being limited to the description that the distance from the channel area CA to the second area A2 is greater than the distance from the channel area CA to the first area A1. Because the first semiconductor layer 1100 is patterned as shown in FIGS. 4 and 5, the above description may indicate that the channel area CA, the first area A1, and the second area A2 are sequentially located along the first semiconductor layer 1100 patterned. Although the channel area CA, the first area A1, and the second area A2 are not sequentially located, the description may suggest that the distance from the channel area CA to the second area A2, measured along the shape of the first semiconductor layer 1100, is greater than the distance from the channel area CA to the first area A1, measured along the shape of the first semiconductor layer 1100. Hereinafter, for convenience, a case where the channel area CA, the first area A1, and the second area A2 are sequentially located along the patterned first semiconductor layer 1100 is described.

The channel area CA of the first semiconductor layer 1100 may be doped with a dopant having a first type that is one of n type and p type, and the first area A1 and the second area A2 may be doped with a dopant having a second type that is the other of the n type and the p type. Such doping may be achieved, for example, by entirely doping the first semiconductor layer 1100 with the dopant having the first type, and then by forming the first gate layer 1200 and doping a portion of the first semiconductor layer 1100, which does not overlap the first gate layer 1200, with the dopant having the second type by using the first gate layer 1200 as a mask. Accordingly, with respect to the first gate layer 1200, the third area A3 of the first semiconductor layer 1100 on the other side of the channel area CA may also be doped with the dopant having the second type. Because the third area A3 is doped concurrently or substantially simultaneously with the first area A1 and the second area A2, a doping concentration in the third area A3 may be substantially the same as doping concentrations in the first area A1 and the second area A2. If suitable, the second area A2 may be additionally doped using a mask, etc. to make the doping concentration in the second area A2 higher than that in the first area A1. When additional doping is performed in the second area A2, the doping concentration in the second area A2 may be higher than that in the third area A3.

If suitable, the first semiconductor layer 1100 may be doped in another method. For example, the first semiconductor layer 1100 may be entirely doped with the dopant having the first type that is one of the n type and the p type, and after the first gate layer 1200 is formed, a portion of the first semiconductor layer 1100, which does not overlap the first gate layer 1200, may be doped with the dopant having the same first type by using the first gate layer 1200 as a mask. Because the third area A3 on the other side of the channel area CA is doped concurrently or substantially simultaneously with the first area A1 and the second area A2, the doping concentration in the third area A3 may be substantially the same as the doping concentrations in the first area A1 and the second area A2. Accordingly, the doping concentrations in the first area A1, the second area A2, and the third area A3 may be higher than the doping concentration in the channel area CA. If suitable, the second area A2 may be additionally doped using a mask, etc. to make the doping concentration in the second area A2 higher than that in the first area A1. When additional doping is performed in the second area A2, the doping concentration in the second area A2 may be higher than that in the third area A3.

A second gate line 1230 may extend in the second direction (the x-axis direction). The second gate line 1230 may correspond to the emission control line EL of FIG. 2. Portions of the second gate line 1230, which overlap the first semiconductor layer 1100, may be the operation control gate electrode of the operation control transistor T5 and the emission control gate electrode of the emission control transistor T6. The emission control signal En may be applied to the pixels through the second gate line 1230.

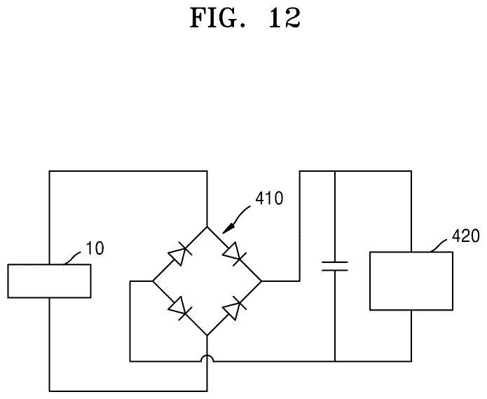

The charging electrode 1240 may be electrically connected to the above-described second area A2 of the first semiconductor layer 1100 through a charging connection electrode 1350 described below. The charging electrode 1240 may be electrically connected to a charging line through a contact hole 1240CNT. For reference, FIG. 11 shows that the charging electrode 1240 contacts a lower metal layer 110, which is interposed between the substrate 100 and the buffer layer 111, through the contact hole 1240CNT. The lower metal layer 110 may be patterned in a wire-like form, and may function as a charging line electrically connected to a battery 420 (e.g., see FIG. 12) and/or a rectifier circuit 410 (e.g., see FIG. 12) of the display apparatus. The charging electrode 1240 may also be connected to a charging line formed as a conductive layer of another layer other than the lower metal layer 110.

As shown in FIG. 5, the charging electrode 1240 may be integral in the first pixel P1 and the second pixel P2 that are adjacent to each other. In this case, the charging electrode 1240 includes a contact hole 1240CNT shared by the first pixel P1 and the second pixel P2, thus being electrically connected to the charging line. As for electric charges supplied to the battery 420, etc. for charging, there is no need to distinguish electric charges from the first pixel P1 from those from the second pixel P2. In addition, as the first pixel P1 and the second pixel P2 share the charging electrode 1240, the structure of the pixels capable of supplying electric charges to the battery 420 may be simplified.

The first gate layer 1200 may include a metal, an alloy, conductive metal oxide, a transparent conductive material, or the like. For example, the first gate layer 1200 may include silver (Ag), an alloy containing Ag, molybdenum (Mo), an alloy containing Mo, aluminum (Al), an alloy containing Al, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. The first gate layer 1200 may have a multilayered structure, for example, a two-layer structure of Mo/Al or a three-layer structure of Mo/Al/Mo.

A second gate-insulating layer (115, see FIG. 11) may cover the first gate layer 1200, and may be located over the first gate-insulating layer 113. The second gate-insulating layer 115 may include an insulating material that is the same as or similar to that of the first gate-insulating layer 113.

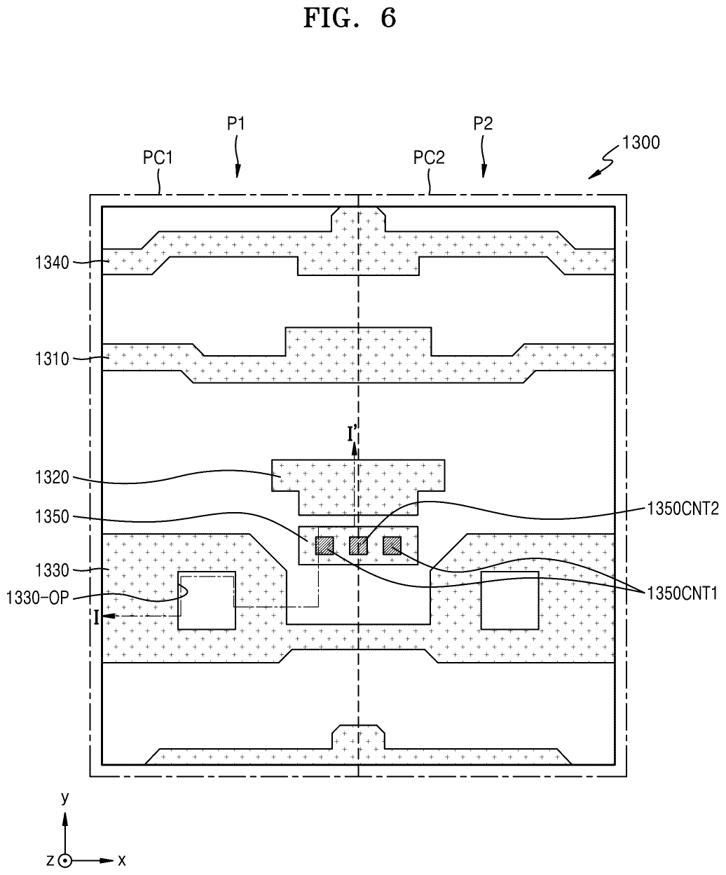

A second gate layer 1300 shown in FIG. 6 may be located over the second gate-insulating layer 115. The second gate layer 1300 may include a third gate line 1310, a fourth gate line 1320, a capacitor upper electrode 1330, a first initialization voltage line 1340 (that is, the first initialization voltage line VL1 of FIG. 5), and the charging connection electrode 1350.

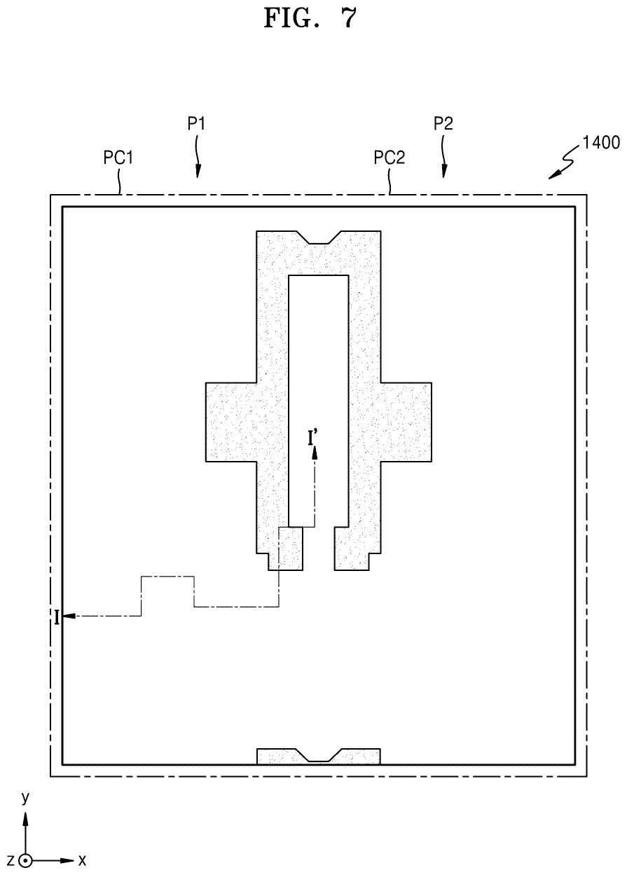

The third gate line 1310 may extend in the second direction (the x-axis direction). The third gate line 1310 may correspond to the previous scan line SLp of FIG. 2. When viewed in the direction perpendicular to the substrate 100 (the z-axis direction), the third gate line 1310 may be spaced apart from the first gate line 1210. The previous scan signal Sn−1 may be applied to the pixels through the third gate line 1310. A portion of the third gate line 1310, which overlaps a second semiconductor layer (1400, see FIG. 7) described below, may be a first initialization lower gate electrode of the first initialization transistor T4.

The fourth gate line 1320 may also extend in the second direction (the x-axis direction), and may have an isolated shape. The fourth gate line 1320 may be electrically connected to a sixth gate line 1530 described below, and may correspond to the second scan line SL2 of FIG. 2. When viewed in the direction perpendicular to the substrate 100 (the z-axis direction), the fourth gate line 1320 may be spaced apart from the first gate line 1210 and the third gate line 1310. The second scan signal Sn′ may be applied to pixels through the fourth gate line 1320. A portion of the fourth gate line 1320, which overlaps the second semiconductor layer 1400 described below, may be a compensation lower gate electrode of the compensation transistor T3.

The third gate line 1310 and the fourth gate line 1320 may be located under the second semiconductor layer 1400 described below with reference to FIG. 7, and may function as lower protective metals that respectively protect portions of the second semiconductor layer 1400 that overlap the third gate line 1310 and the fourth gate line 1320, in addition to functioning as gate electrodes.

The capacitor upper electrode 1330 may overlap the driving gate electrode 1220, and may extend in the second direction (the x-axis direction). The capacitor upper electrode 1330 may correspond to the second capacitor electrode CE2 of FIG. 2, and may form the storage capacitor Cst together with the driving gate electrode 1220. The driving voltage ELVDD may be applied to the capacitor upper electrode 1330. Also, a hole penetrating the capacitor upper electrode 1330 may be formed in the capacitor upper electrode 1330, and at least a portion of the driving gate electrode 1220 may overlap the hole.

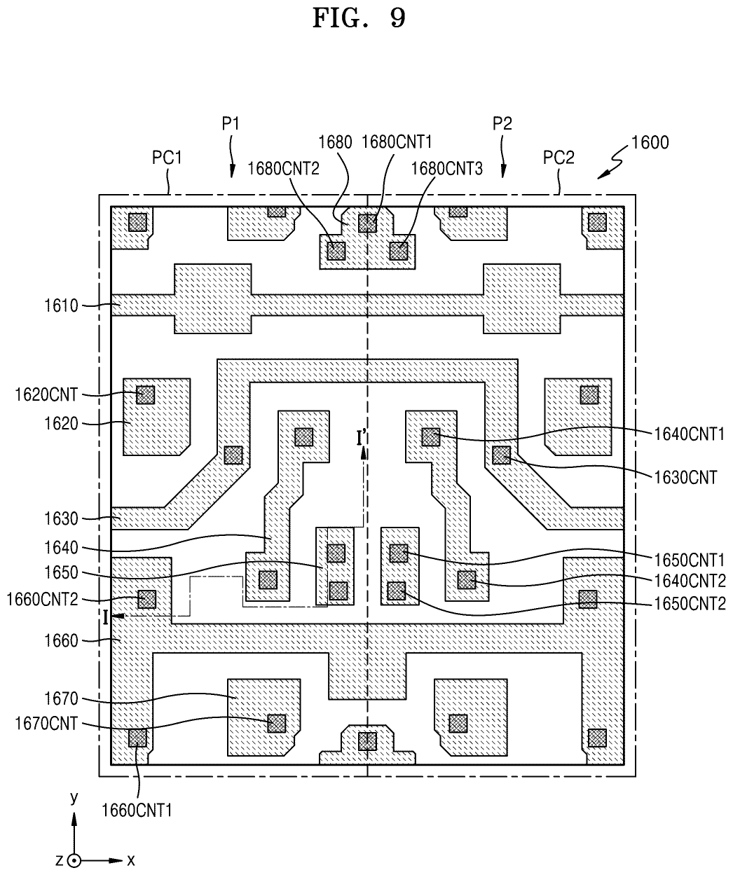

The first initialization voltage line 1340 corresponding to the first initialization voltage line VL1 of FIG. 2 may extend in the second direction (the x-axis direction). When viewed in the direction perpendicular to the substrate 100 (the z-axis direction), the first initialization voltage line 1340 may be spaced apart from the third gate line 1310. The first initialization voltage Vint1 may be applied to pixels through the first initialization voltage line 1340. The first initialization voltage line 1340 may at least partially overlap the second semiconductor layer 1400 described below, and may be configured to transmit the first initialization voltage Vint1 to the second semiconductor layer 1400. The first initialization voltage line 1340 may be electrically connected to the second semiconductor layer 1400 through contact holes 1680CNT1, 1680CNT2, and 1680CNT3 described below with reference to FIG. 9.

The charging connection electrode 1350 may contact the second area A2 of the first semiconductor layer 1100 through at least one contact hole 1350CNT1. The charging connection electrode 1350 may contact the charging electrode 1240 through the contact hole 1350CNT2. Accordingly, the second area A2 of the first semiconductor layer 1100 may be electrically connected to the charging line through the charging connection electrode 1350 and the charging electrode 1240. For reference, FIG. 11 shows that the charging electrode 1240 contacts the lower metal layer 110 interposed between the substrate 100 and the buffer layer 111 through the contact hole 1240CNT. The lower metal layer 110 may be patterned in a wire-like form, and may function as a charging line electrically connected to a battery 420 (e.g., see FIG. 12) and/or a rectifier circuit 410 (e.g., see FIG. 12) of the display apparatus. The charging electrode 1240 may also be connected to a charging line formed as a conductive layer of another layer other than the lower metal layer 110.

As shown in FIG. 6, the charging electrode 1240 may be integral in the first pixel P1 and the second pixel P2 that are adjacent to each other. In this case, the charging connection electrode 1350 may include, or define, the contact hole 1350CNT1 contacting the second area A2 of the first semiconductor layer 1100 of the first pixel P1, and the contact hole 1350CNT1 contacting the second area A2 of the first semiconductor layer 1100 of the second pixel P2. The charging connection electrode 1350 includes, or defines, the contact hole 1350CNT2 shared by the first pixel P1 and the second pixel P2, thus being electrically connected to the charging electrode 1240. As for electric charges supplied to the battery 420, etc. for charging, there is no need to distinguish electric charges from the first pixel P1 from those from the second pixel P2. In addition, as the first pixel P1 and the second pixel P2 share the charging connection electrode 1350, the structure of the pixels capable of supplying electric charges to the battery 420 may be simplified.

For reference, just as the charging connection electrode 1350 contacts the second area A2 of the first semiconductor layer 1100, a fourth transmission line 1650 (e.g., see FIG. 9) described below may contact the first area A1 of the first semiconductor layer 1100. In this point of view, the fourth transmission line 1650 may be referred to as a first electrode, and the charging connection electrode 1350 may be referred to as a second electrode.

The second gate layer 1300 may include a metal, an alloy, conductive metal oxide, a transparent conductive material, or the like. For example, the second gate layer 1300 may include Ag, an alloy containing Ag, Mo, an alloy containing Mo, Al, an alloy containing Al, AlN, W, WN, Cu, Ni, Cr, CrN, Ti, Ta, Pt, Sc, ITO, IZO, or the like. The second gate layer 1300 may have a multilayered structure, for example, a two-layer structure of Mo/Al or a three-layer structure of Mo/Al/Mo.

A first interlayer insulating layer 117 (e.g., see FIG. 11) may cover the second gate layer 1300, and may be located over the second gate-insulating layer 115. The first interlayer insulating layer 117 may include an insulating material. For example, the first interlayer insulating layer 117 may include SiO₂, SiNₓ, SiOₓN_{y}, Al₂O₃, or the like.

The second semiconductor layer 1400 shown in FIG. 7 may be located over the first interlayer insulating layer 117. As described above, the second semiconductor layer 1400 may include an oxide semiconductor. The second semiconductor layer 1400 may be located on a different layer from the first semiconductor layer 1100, and may not overlap the same when viewed in the direction perpendicular to the substrate 100 (in the z-axis direction).

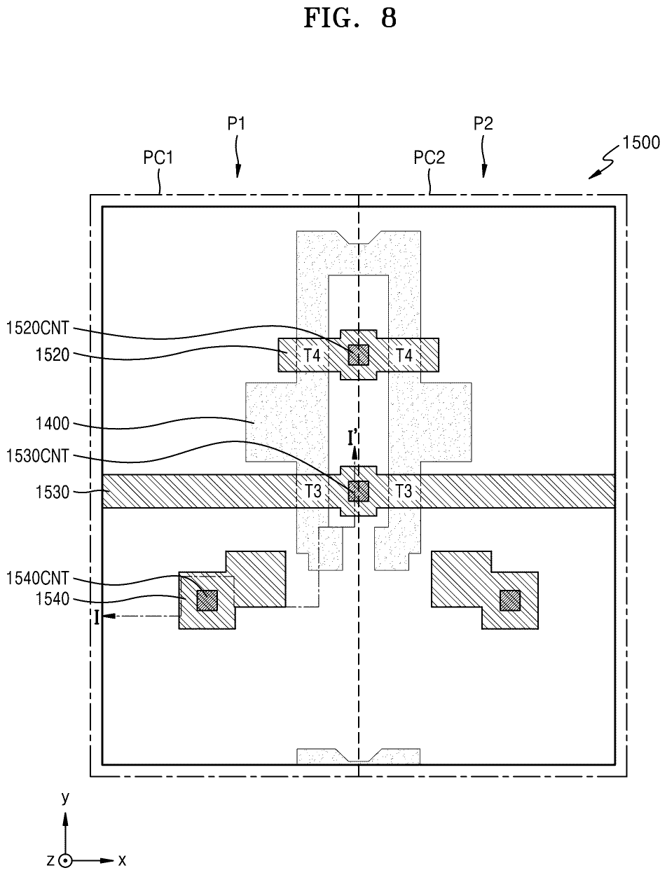

A third gate-insulating layer 118 (e.g., see FIG. 11) may cover the second semiconductor layer 1400, and may be located over the first interlayer insulating layer 117. The third gate-insulating layer 118 may include an insulating material. If suitable, unlike the illustration of FIG. 11, the third gate-insulating layer 118 may be located over only a portion of the second semiconductor layer 1400, and may not be located over the first interlayer insulating layer 117. In this case, the third gate-insulating layer 118 may have the same pattern as a third gate layer 1500 described below with reference to FIG. 8. That is, when viewed in a direction perpendicular to the substrate 100 (the z-axis direction), the third gate-insulating layer 118 may completely or almost completely overlap the third gate layer 1500. This is because the third gate-insulating layer 118 is patterned concurrently or substantially simultaneously with the third gate layer 1500. Therefore, source areas and drain areas of the second semiconductor layer 1400 may not be covered by the third gate-insulating layer 118, except for channel areas overlapping the third gate layer 1500. The third gate-insulating layer 118 may include SiO₂, SiNₓ, SiOₓN_{y}, Al₂O₃, or the like.

A third gate layer 1500 shown in FIG. 8 may be located over the third gate-insulating layer 118. The third gate layer 1500 may include a fifth gate line 1520, a sixth gate line 1530, and a first transmission line 1540.

The fifth gate line 1520 may also extend in the second direction (the x-axis direction), and may have an isolated shape. When viewed in the direction perpendicular to the substrate 100 (the z-axis direction), the fifth gate line 1520 may overlap the third gate line 1310. A portion of the fifth gate line 1520, which overlaps the second semiconductor layer 1400, may be the first initialization upper gate electrode of the first initialization transistor T4. A portion of the second semiconductor layer 1400, which overlaps the fifth gate line 1520, and a portion around the above portion may be referred to as a first initialization semiconductor layer. The fifth gate line 1520 may be electrically connected to the third gate line 1310. For example, the fifth gate line 1520 may be electrically connected to the third gate line 1310 through the contact hole 1520CNT formed in an insulating layer interposed between the fifth gate line 1520 and the third gate line 1310. Accordingly, the fifth gate line 1520 may correspond to the previous scan line SLp of FIG. 2 along with the third gate line 1310. Accordingly, the previous scan signal Sn−1 may be applied to pixels through the fifth gate line 1520 and/or the third gate line 1310.

A sixth gate line 1530 may extend in the second direction (the x-axis direction). When viewed in the direction perpendicular to the substrate 100 (the z-axis direction), the sixth gate line 1530 may overlap the fourth gate line 1320. A portion of the sixth gate line 1530, which overlaps the second semiconductor layer 1400, may be a compensation upper gate electrode of the compensation transistor T3. The sixth gate line 1530 may be electrically connected to the fourth gate line 1320. For example, the sixth gate line 1530 may be electrically connected to the fourth gate line 1320 through the contact hole 1530CNT formed in an insulating layer interposed between the sixth gate line 1530 and the fourth gate line 1320. Accordingly, the sixth gate line 1530 may correspond to the second scan line SL2 of FIG. 2 along with the fourth gate line 1320. Accordingly, the second scan signal Sn′ may be applied to pixels through the sixth gate line 1530 and/or the fourth gate line 1320.

The first transmission line 1540 may be electrically connected to the driving gate electrode 1220 through a contact hole 1540CNT passing through an opening 1330-OP of the capacitor upper electrode 1330 (e.g., see FIG. 6). The first transmission line 1540 may be configured to transmit, to the driving gate electrode 1220, the first initialization voltage Vint1 transmitted through the first initialization transistor T4.

The third gate layer 1500 may include a metal, an alloy, conductive metal oxide, a transparent conductive material, or the like. For example, the third gate layer 1500 may include Ag, an alloy containing Ag, Mo, an alloy containing Mo, Al, an alloy containing Al, AlN, W, WN, Cu, Ni, Cr, CrN, Ti, Ta, Pt, Sc, ITO, IZO, or the like. The third gate layer 1500 may have a multilayered structure, for example, a two-layer structure of Mo/Al or a three-layer structure of Mo/Al/Mo.

A second interlayer insulating layer 119 (e.g., see FIG. 11) may cover at least a portion of the third gate layer 1500 of FIG. 8. The second interlayer insulating layer 119 may include an insulating material. For example, the second interlayer insulating layer 119 may include SiO₂, SiNₓ, SiOₓN_{y}, Al₂O₃, or the like.

A first connection electrode layer 1600 shown in FIG. 9 may be located over the second interlayer insulating layer 119. The first connection electrode layer 1600 may include a horizontal connection line 1610, a second transmission line 1620, a second initialization voltage line 1630, a third transmission line 1640, a fourth transmission line 1650, a fifth transmission line 1660, a sixth transmission line 1670, and a seventh transmission line 1680.

The horizontal connection line 1610 may extend in the second direction (the x-axis direction). The horizontal connection line 1610 may be configured to transmit a data signal to some pixels together with a vertical connection line 1820 (e.g., see FIG. 10).

The second transmission line 1620 may be electrically connected to the first semiconductor layer 1100 through a contact hole 1620CNT (e.g., see FIG. 9). A data signal Dm transmitted through a data line 1810 described below with reference to FIG. 10 may be transmitted to the first semiconductor layer 1100 through the second transmission line 1620, and may be applied to the switching transistor T2.

The second initialization voltage line 1630 may extend in the second direction (the x-axis direction). The second initialization voltage line 1630 corresponding to the second initialization voltage line VL2 of FIG. 2 may be configured to transmit the second initialization voltage Vint2 to pixels. The second initialization voltage line 1630 may be electrically connected to the first semiconductor layer 1100 through the contact hole 1630CNT, and the second initialization voltage Vint2 may be transmitted to the first semiconductor layer 1100, and may be applied to the second initialization transistor T7.

The third transmission line 1640 may electrically connect the second semiconductor layer 1400 to the first transmission line 1540 through contact holes 1640CNT1 and 1640CNT2 respectively formed in one side and the other side of the third transmission line 1640. Because the first transmission line 1540 is electrically connected to the driving gate electrode 1220, the third transmission line 1640 may consequently electrically connect the driving gate electrode to the first initialization semiconductor layer that is a portion of the second semiconductor layer 1400. The first initialization voltage Vint1 may be transmitted to the driving gate electrode 1220 through the second semiconductor layer 1400, the third transmission line 1640, and the first transmission line 1540.

The fourth transmission line 1650 may electrically connect the second semiconductor layer 1400 to the first semiconductor layer 1100 through contact holes 1650CNT1 and 1650CNT2 formed in one side and the other side of the fourth transmission line 1650. That is, the fourth transmission line 1650 may contact the first area A1 of the first semiconductor layer 1100 through the contact hole 1650CNT2 and the second semiconductor layer 1400 through the contact hole 1650CNT1. Accordingly, the fourth transmission line 1650 may electrically connect the compensation transistor T3 to the driving transistor T1. The fourth transmission line 1650 contacting the first area A1 of the first semiconductor layer 1100 through the contact hole 1650CNT2 may be electrically connected to a pixel electrode 310 through the emission control transistor T6, the sixth transmission line 1670, and a tenth transmission line 1840 (e.g., see FIG. 10). This is because the first area A1 of the first semiconductor layer 1100 contacting the fourth transmission line 1650 is integrally formed with a semiconductor layer of the emission control transistor T6.

The fifth transmission line 1660 may extend in the second direction (the x-axis direction). The driving voltage ELVDD, which is a constant voltage from the driving voltage line 1830 described below with reference to FIG. 10, may be transmitted to the fifth transmission line 1660, and the fifth transmission line 1660 may be electrically connected to the first semiconductor layer 1100 through a contact hole 1660CNT1, and may be configured to transmit the driving voltage ELVDD to the first semiconductor layer 1100, for example, during the operation control transistor T5. Also, the fifth transmission line 1660 electrically connected to the capacitor upper electrode 1330 (that is, the second capacitor electrode CE2 of FIG. 2) through the contact hole 1660CNT2 may be configured to transmit the driving voltage ELVDD to the capacitor upper electrode 1330.

The sixth transmission line 1670 may be electrically connected to the first semiconductor layer 1100 through a contact hole 1670CNT. The sixth transmission line 1670 may be configured to transmit the driving current or the second initialization voltage Vint2 from the first semiconductor layer 1100 to the organic light-emitting diode OLED.

The seventh transmission line 1680 may be electrically connected to the second semiconductor layer 1400 through contact holes 1680CNT2 and 1680CNT3. The seventh transmission line 1680 may be electrically connected to the first initialization voltage line 1340 of FIG. 6 through a contact hole 1680CNT1. To this end, the seventh transmission line 1680 may be configured to transmit the first initialization voltage Vint1 from the first initialization voltage line 1340 to the first initialization transistor T4.

The first connection electrode layer 1600 may include a metal, an alloy, conductive metal oxide, a transparent conductive material, or the like. For example, the first connection electrode layer 1600 may include Ag, an alloy containing Ag, Mo, an alloy containing Mo, Al, an alloy containing Al, AlN, W, WN, Cu, Ni, Cr, CrN, Ti, Ta, Pt, Sc, ITO, IZO, or the like. The first connection electrode layer 1600 may have a multilayered structure, for example, a two-layer structure of Ti/Al or a three-layer structure of Ti/Al/Ti.

The third interlayer insulating layer 121 may cover the first connection electrode layer 1600, and may be located over the second interlayer insulating layer 119. The third interlayer insulating layer 121 may include an insulating material. For example, the third interlayer insulating layer 121 may include SiO₂, SiNₓ, SiOₓN_{y}, Al₂O₃, or the like. According to suitability, the third interlayer insulating layer 121 may include an organic insulating material. For example, the third interlayer insulating layer 121 may include photoresist, BCB, polyimide, HMDSO, PMMA, polystyrene, a polymer derivative having a phenol-based group, an acryl-based polymer, an imide-based polymer, an aryl-ether-based polymer, an amide-based polymer, a fluorine-based polymer, a p-xylene-based polymer, a vinyl alcohol-based polymer, or any blend thereof.

A second connection electrode layer 1800 shown in FIG. 10 may be located over the third interlayer insulating layer 121. The second connection electrode layer 1800 may include the data line 1810, the vertical connection line 1820, the driving voltage line 1830, and the tenth transmission line 1840.

The data line 1810 may extend in the first direction (the y-axis direction). The data line 1810 may correspond to the data line DL of FIG. 2. The data line 1810 may be electrically connected to the second transmission line 1620 through a contact hole 1810CNT, and the data signal Dm from the data line 1810 may be transmitted to the first semiconductor layer 1100 through the second transmission line 1620, and may be applied to the switching transistor T2.

The vertical connection line 1820 may substantially extend in the first direction (the y-axis direction). Together with the horizontal connection line 1610, the vertical connection line 1820 may be configured to transmit a data signal to some pixels. To this end, a corresponding vertical connection line 1820 and a corresponding horizontal connection line 1610 may be connected to each other through a contact hole.

The driving voltage line 1830 may substantially extend in the first direction (the y-axis direction). The driving voltage line 1830 may correspond to the driving voltage line PL of FIG. 2. The driving voltage line 1830 may be configured to apply the driving voltage ELVDD to pixels. The driving voltage line 1830 may be electrically connected to a fifth transmission line 1660 through a contact hole 1830CNT, and may be configured to transmit the driving voltage ELVDD to the operation control transistor T5 and the capacitor upper electrode 1330 as described above. The driving voltage line 1830 of the first pixel circuit PC1 may be formed integrally with the driving voltage line 1830 of the second pixel circuit PC2 that is adjacent to the first pixel circuit PC1.

The tenth transmission line 1840 may be electrically connected to the sixth transmission line 1670 through a contact hole 1840CNT1, and may receive, from the sixth transmission line 1670, the driving current or the second initialization voltage Vint2 from the first semiconductor layer 1100. The tenth transmission line 1840 may be configured to transmit the driving current or the second initialization voltage Vint2 from the first semiconductor layer 1100 to the pixel electrode of the organic light-emitting diode OLED through a contact hole 1840CNT2 formed in an insulating layer located over the tenth transmission line 1840.

The second connection electrode layer 1800 may include a metal, an alloy, conductive metal oxide, a transparent conductive material, or the like. For example, the second connection electrode layer 1800 may include Ag, an alloy containing Ag, Mo, an alloy containing Mo, Al, an alloy containing Al, AlN, W, WN, Cu, Ni, Cr, CrN, Ti, Ta, Pt, Sc, ITO, IZO, or the like. The second connection electrode layer 1800 may have a multilayered structure, for example, a two-layer structure of Ti/Al or a three-layer structure of Ti/Al/Ti.

A planarization insulating layer 125 shown in FIG. 11 may cover the second connection electrode layer 1800, and may be located over the third interlayer insulating layer 121. The planarization insulating layer 125 may include an organic insulating material. For example, the planarization insulating layer 125 may include photoresist, BCB, polyimide, HMDSO, PMMA, polystyrene, a polymer derivative having a phenol-based group, an acryl-based polymer, an imide-based polymer, an aryl-ether-based polymer, an amide-based polymer, a fluorine-based polymer, a p-xylene-based polymer, a vinyl alcohol-based polymer, or any blend thereof.

As shown in FIG. 11, the organic light-emitting diode OLED may be located over the planarization insulating layer 125. The organic light-emitting diode OLED may include the pixel electrode 310, an intermediate layer 320 including an emission layer, and an opposite electrode 330.

The pixel electrode 310 may be a (semi-) light-transmissive electrode or a reflection electrode. For example, the pixel electrode 310 may include a reflection layer including Ag, magnesium (Mg), Al, Pt, palladium (Pd), gold (Au), Ni, neodymium (Nd), iridium (Ir), Cr, or a combination thereof, and a transparent or translucent electrode layer formed on the reflection layer. The transparent or translucent electrode layer may include at least one material selected from the group consisting of ITO, IZO, zinc oxide (ZnO or ZnO₂), indium oxide (In₂O₃), indium gallium oxide (IGO), or aluminum zinc oxide (AZO). For example, the pixel electrode 310 may have a three-layer structure of ITO/Ag/ITO.

A pixel-defining layer 127 may be located over the planarization insulating layer 125. The pixel-defining layer 127 may include an opening OP exposing a central portion of the pixel electrode 310. The pixel-defining layer 127 may increase a distance between the edge of the pixel electrode 310 and the opposite electrode 330 located over the pixel electrode 310, and thus may reduce or prevent the likelihood of arcs, etc. from being generated on the edge of the pixel electrode 310.

The pixel-defining layer 127 may include one or more organic insulating materials selected from the group consisting of polyimide, polyamide, acryl resin, BCB, or phenol resin and may be formed through a spin-coating method or the like.

At least a portion of the intermediate layer 320 of the organic light-emitting diode OLED may be located in the opening OP formed in the pixel-defining layer 127. The emission area of the organic light-emitting diode OLED may be defined by the opening OP.

The intermediate layer 320 may include an emission layer. The emission layer may include an organic material including a fluorescent or phosphorescent material emitting red light, green light, blue light, or white light. The emission layer may include a low-molecular-weight or a high-molecular-weight organic material, and on and under the emission layer, functional layers, such as a hole transport layer (HTL), a hole injection layer (HIL), an electron transport layer (ETL), and an electron injection layer (EIL) may be selectively arranged.

The emission layer may be patterned to correspond to each pixel electrode 310. Various modifications may be made to layers included in the intermediate layer 320 other than to the emission layer. For example, the layers may be integrated over the sub-pixel electrodes 210.

The opposite electrode 330 may be a light-transmissive electrode or a reflection electrode. For example, the opposite electrode 330 may be a transparent or translucent electrode, and may include Li, Ca, LiF, Al, Ag, Mg, or a compound thereof. Also, the opposite electrode 330 may further include a transparent conductive oxide (TCO) layer that may include ITO, IZO, ZnO, or In₂O₃, and may be located over the metal thin-film. The opposite electrode 330 may be integrally formed over the entire display area DA, and may be located over the intermediate layer 320 and the pixel-defining layer 127.

The organic light-emitting diode OLED may be covered by a thin-film encapsulation layer or an encapsulation layer. In one or more embodiments, the thin-film encapsulation layer may include at least one inorganic encapsulation layer and at least one organic encapsulation layer. For example, the thin-film encapsulation layer may include a first inorganic encapsulation layer, a second inorganic encapsulation layer, and an organic encapsulation layer therebetween.

The first inorganic encapsulation layer and the second inorganic encapsulation layer may each include at least one inorganic insulating material, such as SiO₂, SiNₓ, SiOₓN_{y}, Al₂O₃, titanium oxide (TiO₂), tantalum oxide (Ta₂O₅), hafnium oxide (HfO₂), or ZnO₂, and may be formed through CVD, etc. The organic encapsulation layer may include a polymer-based material. The polymer-based material may include silicon-based resin, acryl-based resin (e.g., PMMA, polyacrylic acid, etc.), epoxy-based resin, polyimide, polyethylene, and the like.

The first inorganic encapsulation layer, the organic encapsulation layer, and the second inorganic encapsulation layer may be integrally formed as a single body to cover the display area DA.

As described above, the channel area CA of the first semiconductor layer 1100 may be doped with the dopant having the first type that is one of the n type and p type, and the first area A1 and the second area A2 may be doped with the dopant having the second type that is the other of the n type and the p type. Accordingly, a portion of the first semiconductor layer 1100, which corresponds to the driving transistor T1, may include a P-N junction area formed by the first area A1, the second area A2, and the channel area CA. When light, such as ultraviolet rays, which is incident to the display apparatus from the outside thereof reaches the P-N junction area, currents may flow in the P-N junction area. Therefore, while no images are displayed in the display area DA of the display apparatus, the battery 420, etc. of the display apparatus are charged using the currents flowing in the P-N junction area, enabling the realization of a display apparatus that may be used for an extended period of time even with an existing battery.

To increase the amount of currents generated in the P-N junction areas, it is good to increase the area or length of the P-N junction area. The first area A1 of the first semiconductor layer 1100 may be an essential component to realize the pixel circuit PC described above with reference to FIG. 2. Therefore, it may also be considered to implement a P-N junction area for charging the battery 420, etc. by using only the channel area CA and the first area A1. However, in the case of the display apparatus according to one or more embodiments, the first semiconductor layer 1100 is designed to include not only the first area A1 but also the second area A2, and a P-N junction area for charging the battery 420, etc. is realized by using the channel area CA, the first area A1, and the second area A2. Accordingly, the amount of currents generated in the P-N junction area may be effectively increased.

In addition, in the case of the display apparatus according to one or more embodiments, the second area A2 is located farther from the channel area CA than the first area A1 as described above, and thus, the amount of currents generated in the P-N junction area may be significantly increased. Here, the description that the second area A2 is located farther from the channel area CA than the first area A1 may indicate that the channel area CA, the first area A1, and the second area A2 are sequentially located along the patterned first semiconductor layer 1100, as described above. Although the channel area CA, the first area A1, and the second area A2 are not sequentially located, the description may suggest that the distance from the channel area CA to the second area A2, measured along the shape of the first semiconductor layer 1100, is greater than the distance from the channel area CA to the first area A1, measured along the shape of the first semiconductor layer 1100.

In the case of the display apparatus according to one or more embodiments, the charging electrode 1240 is in contact with the second area A2 and is electrically connected to the lower metal layer 110 patterned in the wire-like form, and the lower metal layer 110 functioning as a charging line is electrically connected to the battery 420 and/or the rectifier circuit 410 of the display apparatus, thereby realizing a display apparatus that may be used for an extended period of time even with an existing battery.

However, one or more embodiments are not limited to using the lower metal layer 110 as a charging line. For example, the horizontal connection line 1610 and the vertical connection line 1820 may be configured to transmit data signals to some pixels. However, not every horizontal connection line 1610 and vertical connection line 1820 serves to transmit data signals. Therefore, the charging electrode 1240 is electrically connected to the horizontal connection line 1610 and/or the vertical connection line 1820 that do not transmit data signals, and the horizontal connection line 1610 and/or the vertical connection line 1820 is electrically connected to the battery 420 and/or the rectifier circuit 410 of the display apparatus, thereby realizing a display apparatus that may be used for an extended period of time even with an existing battery.

In addition, the doping concentration in the second area A2 may be higher than that in the first area A1. To this end, the charging efficiency may increase by increasing the number of electrons induced to the second area A2.

As shown in FIG. 11, the substrate 100 may include two layers 101 and 103 including the above-described polymer resin and a substrate intermediate layer 102 interposed between the two layers 101 and 103. That is, the substrate 100 may include a first substrate 103, a second substrate 101 located over the first substrate 103, and the substrate intermediate layer 102 interposed therebetween. The substrate intermediate layer 102 may bond the two layers 101 and 103, and may function as a barrier that reduces or prevents external impurities from passing through the substrate 100. Furthermore, the substrate intermediate layer 102 may include amorphous silicon or crystalline silicon. In this case, when light, such as, ultraviolet rays, from the outside is irradiated onto the substrate intermediate layer 102, an electron-hole pair may be generated in the substrate intermediate layer 102. In this case, when an on-bias is applied from the driving transistor T1, etc. arranged above the substrate intermediate layer 102, electrons or holes may move. The battery 420, etc. are charged using not only the electric charges generated in the P-N junction area of the first semiconductor layer 1100, but also the electric charges generated in the substrate intermediate layer 102, and thus, the charging efficiency may be greatly increased. For example, because amorphous silicon has a light absorption coefficient that is about 10 times greater than crystalline silicon, the efficiency may be enhanced by allowing the substrate intermediate layer 102 to include amorphous silicon.

Because the second area A2 of the first semiconductor layer 1100 may be electrically connected to the battery 420 as described above, FIG. 12 is a schematic conceptual view showing such a configuration. As shown in FIG. 12, the display panel 10 may be electrically connected to the battery 420. Accordingly, images may be produced in the display area DA by receiving power from the battery 420, and when no images are produced in the display area DA, electric charges generated using external light may be supplied to the battery 420 to charge the same. The connection of the display panel 10 to the battery 420 for the charging may imply an electrical connection of the charging electrode 1240, which is in contact with the second area A2 of the first semiconductor layer 1100, to the battery 420 through the charging line, etc. Such a connection may be construed as an electrical connection of the second area A2 of the first semiconductor layer 1100 to the battery 420. As shown in FIG. 12, the second area A2 of the first semiconductor layer 1100 may be electrically connected to the rectifier circuit 410 through the charging line, etc., and the rectifier circuit 410 may be electrically connected to the battery 420. The rectifier circuit 410 may rectify an electrical signal supplied to the battery 420 by using a diode, etc., and may protect the battery 420 by using a capacitor.

According to the one or more embodiments, a display apparatus that may be used for an extended period of time even with an existing battery may be realized. However, the scope of the disclosure is not limited by the effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

What is claimed is:

1. A display apparatus comprising:
a substrate;
a semiconductor layer over the substrate, and comprising a first area, a second area, and a channel area;
a gate electrode over the semiconductor layer, and overlapping the channel area; and
a pixel electrode electrically connected to the first area that is in one direction from the channel area of the semiconductor layer,
wherein the second area is farther than the first area from the channel area.

2. The display apparatus of claim 1, wherein the second area is in the one direction from the channel area.

3. The display apparatus of claim 1, further comprising:
a first electrode contacting the first area, and electrically connected to the pixel electrode; and
a second electrode contacting the second area.

4. The display apparatus of claim 1, wherein the substrate comprises:
a first substrate;
a second substrate over the first substrate; and
a substrate intermediate layer between the first substrate and the second substrate.

5. The display apparatus of claim 4, wherein the substrate intermediate layer comprises amorphous silicon or crystalline silicon.

6. The display apparatus of claim 1, wherein the channel area is doped with a dopant having a first type that is one of an n type and a p type, and each of the first area and the second area is doped with a dopant having a second type that is another of the n type and p type.

7. The display apparatus of claim 6, wherein a doping concentration in the second area is higher than a doping concentration in the first area.

8. The display apparatus of claim 7, wherein a third area that is in another direction from the channel area is doped with the dopant having the second type.

9. The display apparatus of claim 8, wherein a doping concentration in the second area is higher than a doping concentration in the third area.

10. The display apparatus of claim 8, wherein a doping concentration in the first area is substantially equal to a doping concentration in the third area.

11. The display apparatus of claim 1, further comprising a battery configured to drive the display apparatus,
wherein the second area is electrically connected to the battery.

12. The display apparatus of claim 11, wherein the second area is electrically connected to a rectifier circuit that is electrically connected to the battery.

13. The display apparatus of claim 1, wherein the gate electrode is of a driving transistor.

14. A display apparatus comprising:
a substrate;
a gate electrode over the substrate;
a semiconductor layer between the substrate and the gate electrode, and comprising a first area, a second area, and a channel area overlapping the gate electrode, the first area being in one direction from the channel area, the second area being farther from the channel area than the first area;
a charging connection electrode contacting the second area; and
a battery electrically connected to the charging connection electrode.

15. The display apparatus of claim 14, wherein the second area is in the one direction from the channel area.

16. The display apparatus of claim 14, further comprising:
a transmission line contacting the first area; and
a pixel electrode electrically connected to the transmission line.

17. The display apparatus of claim 14, wherein the substrate comprises:
a first substrate;
a second substrate over the first substrate; and
a substrate intermediate layer between the first substrate and the second substrate.

18. The display apparatus of claim 17, wherein the substrate intermediate layer comprises amorphous silicon or crystalline silicon.

19. The display apparatus of claim 14, wherein the channel area is doped with a dopant having a first type that is one of an n type and a p type, and the first area and the second area are doped with a dopant having a second type that is another of the n type and p type.

20. The display apparatus of claim 19, wherein a doping concentration in the second area is higher than a doping concentration in the first area.
